(19) United States
(12) Patent Application Publication
(10) Pub. No.: US 2004/0241956 A1
(43) Pub. Date: Dec. 2, 2004

(54) Methods of forming trench isolation regions using chemical mechanical polishing and etching

(76) Inventors: Dong-seog Eun, Gyeonggi-do (KR); Kwang-shik Shin, Seoul (KR); Kyu-charn Park, Gyeonggi-do (KR); Han-soo Kim, Gyeonggi-do (KR)

Correspondence Address: MYERS BIGEL SIBLEY & SAJOVEC, PO BOX 37428, RALEIGH, NC, 27627, US

(21) Appl. No.: 10/851,716

(22) Filed: May 21, 2004

(30) Foreign Application Priority Data
May 30, 2003 (KR) 10-2003-0034896

(51) Int. Cl. H01L 21/76

(52) U.S. Cl. 438/424; 438/435

(57) ABSTRACT

A trench isolation region can be formed in a device substrate by planarizing a first insulation layer in a trench of a substrate using chemical mechanical polishing so that the first insulation layer is removed from a surface of the substrate outside the trench and remains inside the trench, thereby forming an opening to a void beneath a surface of the first insulation layer. A further portion of the first insulation layer can be removed from inside the trench using a wet etch or a dry etch process to increase the opening to the void. A second insulation layer can be deposited in the void in the first insulation layer through the increased opening.

### CROSS-REFERENCE TO RELATED APPLICATION

This application claims priority to Korean Patent Application No. 2003-34896, filed on May 30, 2003, in the Korean Intellectual Property Office, the content of which is incorporated herein by reference in its entirety.

### FIELD OF THE INVENTION

The invention relates to methods of forming integrated circuit devices and, more specifically, to methods of forming trench isolation regions in integrated circuit devices.

### BACKGROUND

Generally, isolation regions may be formed on a substrate as part of a broader goal of forming transistors and capacitors in integrated circuit (i.e., semiconductor) devices. Isolation regions can be used to electrically isolate devices on the same substrate from one another. It is known to use LOCOS (local oxidation of silicon) and PBL (poly-silicon buffered LOCOS) techniques to form such isolation regions. In some LOCOS techniques, devices can be separated by performing a mask process and an oxidation process with respect to a pad oxide layer and a pad nitride layer of the substrate. In some PBL techniques, a poly-silicon buffer is formed between the pad oxide layer and the pad nitride layer, to grow a field oxide layer.

Some LOCOS techniques may not perform as needed in forming highly integrated semiconductor devices. Accordingly, STI (shallow trench isolation) techniques have been used to form isolation regions in semiconductor devices, which may offer an increased level of integration compared to LOCOS in forming semiconductor devices where features therein measure less than 0.25 μm.

In some conventional STI techniques, trenches are formed by etching the substrate to a certain depth. Next, an oxide layer can be deposited on the whole surface of the substrate and in the trenches. Portions of the oxide layer on the substrate (outside the trench) may be etched using a CMP (chemical mechanical polishing) process. Then, the isolation layer can then be cleaned.

However, there may be disadvantages associated with the conventional STI techniques discussed above. For example, as “nanotechnology” develops, the pitch (i.e., distance of between features on the substrate) may be further reduced. Accordingly, the width of STI trenches may be so small that it may be difficult to form an insulation layer in such a narrow (and deep) trench without forming voids therein. If a void is formed in the insulating layer in the trench, a conductive material, such as silicon, may be deposited in the void during a subsequent process, which may cause a fault in the semiconductor device (e.g., by forming a bridge between cells which otherwise are to be electrically isolated from one another).

A method of forming semiconductor devices to reduce voids using an etch back process is discussed, for example, in Korean Patent Application No. 10-2000-0085198, which is discussed briefly below in reference to FIGS. 1 to 3. Referring to FIG. 1, a pad oxide layer 12 and a pad nitride layer 13 are formed on a substrate 11. The substrate 11 is etched to form a trench 11a and a first insulation layer 14 is formed therein and on the substrate 11 outside the trench 11a. As shown in FIG. 1, a void 15a is formed in the first insulation layer 14 in the trench 11a.

Referring to FIG. 2, the first insulation layer 14 is partially removed by an etch-back (using a dry etch or a wet etch) to the point where the void 15a may begin within the trench 11a. If a portion of the void 15a remains after etching the first insulation layer 14, a seam 15b may be left in the exposed surface of the first insulation layer 14. Referring to FIG. 3, a second insulation layer 16 is deposited in the trench 11a on the seam 15b and a chemical mechanical polishing process is performed so that the seam 15b is buried under the second insulation layer 16 in the trench 11a. However, the etchant may flow into the seam 15b during the etch back process, so that the substrate 11 may be unintentionally etched. In addition, the pad oxide layer 12 may be damaged during etch back process.

A method for fabricating semiconductor devices using chemical mechanical polishing process is discussed, for example, in Japanese Patent Publication No. H11-284061, which is discussed briefly herein in reference to FIGS. 4 to 6. Referring to FIG. 4, a trench 16′ is formed by etching the substrate 10′, a pad oxide layer 12′, and the pad nitride layer 14′. A first CVD oxide layer 18′ is formed in the trench 16′, so that a seam 20′ is formed therein.

Referring to FIG. 5, a chemical mechanical polishing process is performed on the first CVD oxide layer 18′ to form a recessed center portion. As shown, however, peripheral portions of the first CVD oxide layer 18′ close to an edge of the trench 16′ may not be recessed by the CMP.

Referring to FIG. 6, a second CVD oxide layer 22′ is deposited in the recessed center portion and is planarized. As a result, the trench isolation region is formed with the seam 20′ under the second CVD oxide layer 22′ as shown. As shown above, the center portion of the trench 16′ may not by recessed deep enough by the CMP to remove the seam 20′ in highly integrated devices (e.g., in devices where the widths of trenches are less than about 100 nm).

### SUMMARY

Embodiments according to the invention can provide methods of forming isolation regions using chemical mechanical polishing and etching to increase void openings for deposition of insulation layers therein. Pursuant to these embodiments, a trench isolation region can be formed in a device substrate by planarizing a first insulation layer in a trench of a substrate using chemical mechanical polishing so that the first insulation layer is removed from a surface of the substrate outside the trench and remains inside the trench, thereby forming an opening to a void beneath a surface of the first insulation layer. A further portion of the first insulation layer can be removed from inside the trench using a wet etch or a dry etch process to increase the opening to the void. A second insulation layer can be deposited in the void in the first insulation layer through the increased opening.

In some embodiments according to the invention, the further portion is removed and then removing the first insulation layer from inside the trench is ceased to avoid exposing an oxide pad layer located beneath the surface of the substrate. In some embodiments according to the invention, the first insulation layer in the trench is wet-etched using an HF etchant diluted in a ratio of about 200:1 mixed with deionized water.

In some embodiments according to the invention, the first insulation layer is wet-etched to remove about 100 Angstroms from the surface of the first insulation layer. In some embodiments according to the invention, the second insulation layer is planarized to remove the second insulation layer from the surface outside the trench and to avoid removing the second insulation layer from inside the trench. In some embodiments according to the invention, the second insulation layer is deposited to a thickness of about 1000 Angstroms.

In some embodiments according to the invention, the first insulation layer in a trench is planarized using chemical mechanical polishing and then the surface is examined to determine if the opening of the void is present. The surface of the first insulation layer is cleaned responsive to determining that the opening of the void is not present.

In some embodiments according to the invention, the first insulation layer in the trench is plananrized using chemical mechanical polishing so that the first insulation layer is removed from the surface of the substrate outside the trench and remains inside the trench. The surface of the first insulation layer in the trench is examined to determine if an opening of a void in the first insulation layer is present. The surface of the first insulation layer is cleaned responsive to determining that the opening of the void is not present. A further portion of the first insulation layer is removed from inside the trench using a wet etch or a dry etch process to increase the opening to the void and depositing a second insulation layer in the void in the first insulation layer through the increased opening responsive to determining that the opening of the void is present on the surface of the first insulation layer in the trench.

In some embodiments according to the invention, the second insulation layer in the trench is planarized and the surface of the second insulation layer in the trench is examined to determine if an opening of a void in the second insulation layer is present. The surface of the second insulation layer is cleaned responsive to determining that the opening of the void is not present in the surface of the second insulation layer. A further portion of the second insulation layer is removed from inside the trench using a wet etch or a dry etch process to increase the opening to the void in the second insulation layer and depositing a third insulation layer in the void in the second insulation layer through the increased opening responsive to determining that the opening of the void is present on the surface of the second insulation layer in the trench.

In some embodiments according to the invention, the surface is visually examined using an electron microscope, a scanning electron microscope, or a scanning-tunneling electron microscope.

### BRIEF DESCRIPTION OF THE DRAWINGS

FIGS. 1 to 6 are cross-sectional views that illustrate methods of forming trench isolation regions in integrated circuit devices according to the prior art.

FIGS. 7 to 12 are cross-sectional views that illustrate method embodiments of forming trench isolation regions in integrated circuit devices according to the invention.

FIG. 13 is a flowchart that illustrates method embodiments of forming trench isolation regions in the integrated circuit devices according to the invention.

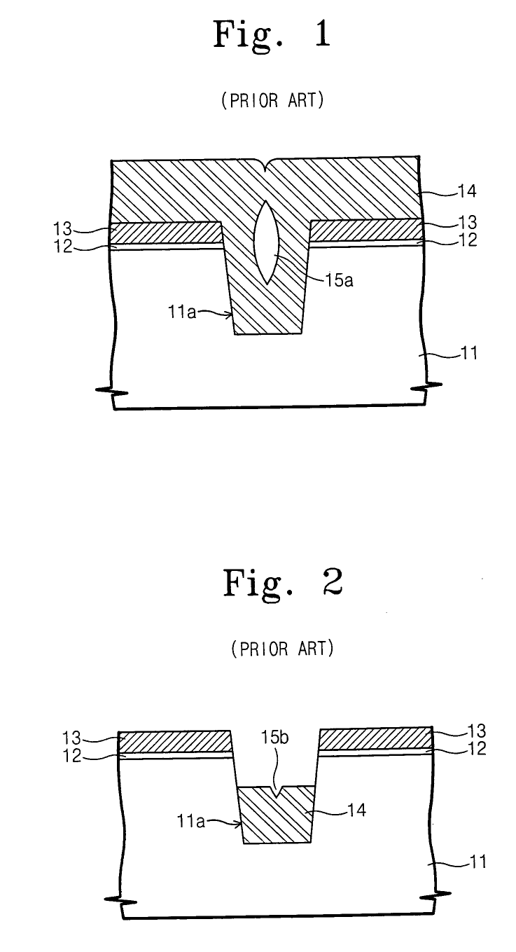

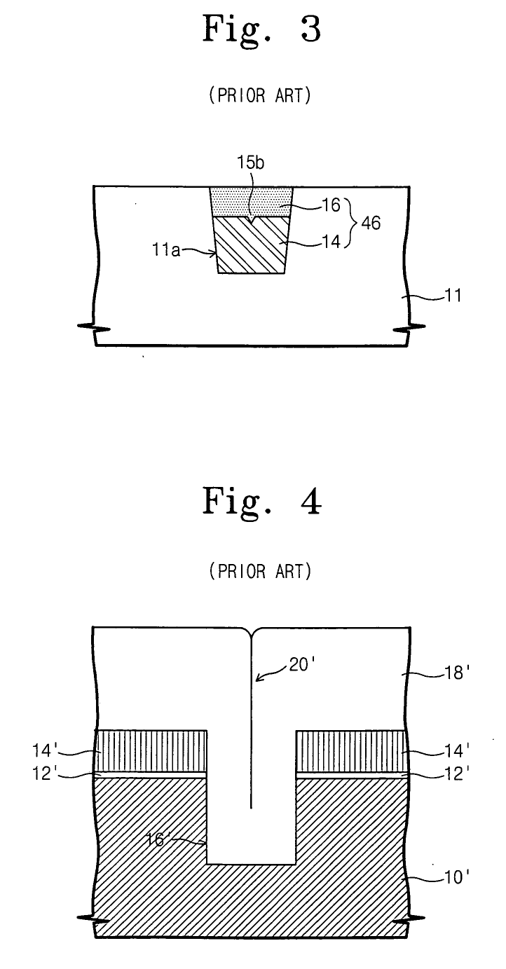

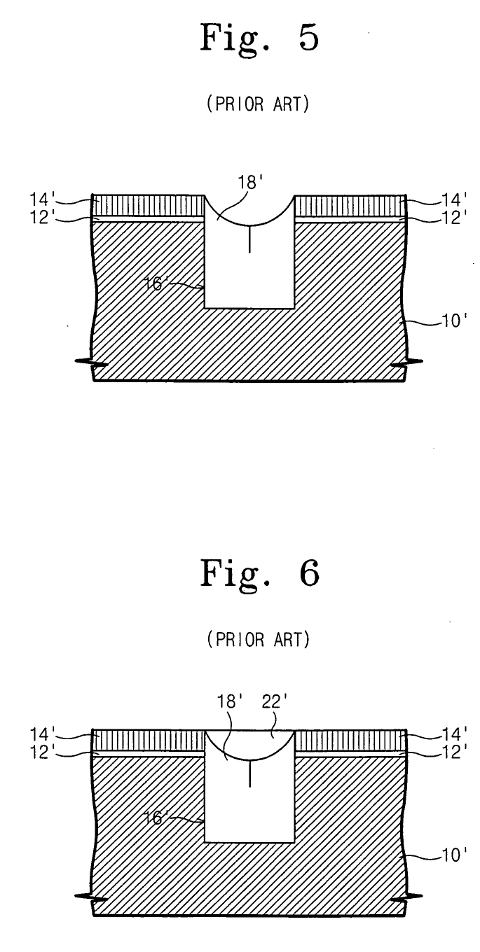

### DETAILED DESCRIPTION OF EMBODIMENTS ACCORDING TO THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” another element, it can be directly on the other element or intervening elements may also be present. Furthermore, relative terms such as “lower” or “upper” may be used herein to describe a relationship of one layer or region to another layer or region relative to a substrate or base layer as illustrated in the figures. It will be understood that these terms are intended to encompass different orientations of the device in addition to the orientation depicted in the figures. Finally, the term “directly” means that there are no intervening elements. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first region, layer or section discussed below could be termed a second region, layer or section, and, similarly, a second region, layer or section could be termed a first region, layer or section without departing from the teachings of the invention.

Relative terms, such as “beneath” and “above”, may be used herein to describe one elements relationship to another elements as illustrated in the Figures. It will be understood that relative terms are intended to encompass different orientations of the device in addition to the orientation depicted in the Figures. For example, if the device in the Figures is turned over, elements described as being “beneath” the other elements would then be oriented “above” the other elements. The exemplary term “beneath”, can therefore, encompasses both an orientation of beneath and above, depending of the particular orientation of the figure.

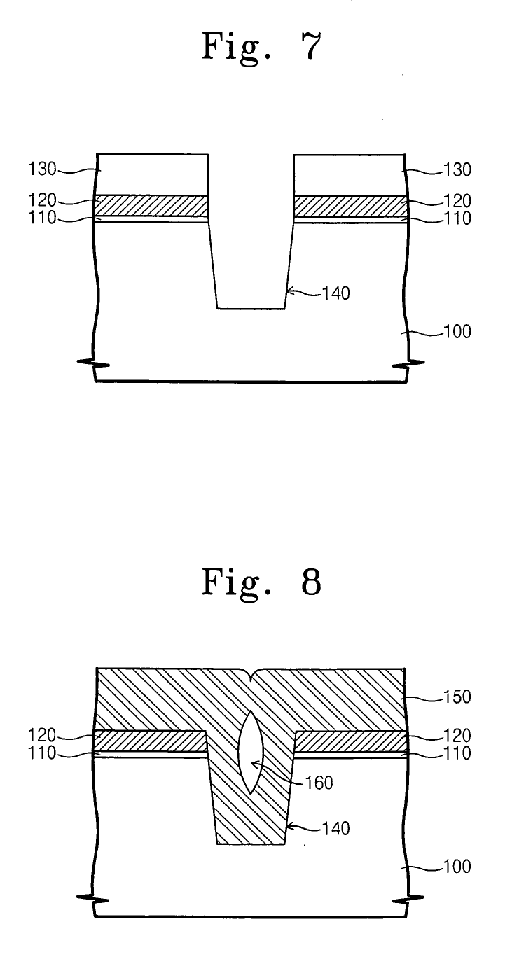

FIGS. 7 to 12 are cross-sectional views of trench isolation regions in integrated circuit devices formed according to some method embodiments of the invention. FIG. 13 is a flowchart showing method embodiments of forming trench isolation regions in integrated circuit devices according to the invention.

Referring to FIG. 7, a substrate 100 includes silicon that can be used to fabricate semiconductor chips thereon. A pad oxide layer 110 and a pad nitride layer 120 are formed by thermal oxidation and nitridation, respectively. In some embodiments according to the invention, the pad oxide layer 110 and the pad nitride layer 120 are formed to thicknesses of about 100 Angstroms and about 400 Angstroms, respectively. The pad nitride layer 120 can provide a polishing stop layer during a subsequent chemical mechanical polishing (CMP) to planarize the substrate 100. The pad oxide layer 110 can reduce stress between the pad nitride layer 120 and the substrate 100.

In some embodiments according to the invention, an anti-reflection layer 130 is formed to reduce (or prevent) inadequate patterning (e.g., changes in line width caused by interference and reflection of light in a subsequent photolithography process). In some embodiments according to the invention, the anti-reflection layer 130 is formed to a thickness of about 1500 Angstroms.

The anti-reflection layer 130, the pad nitride layer 120, the pad oxide layer 110, and the substrate 100 are patterned (via photolithography) and etched to form a trench 140 in the substrate 100, to subsequently provide an isolation region therein. In some embodiments according to the invention, the trench 140 is formed to a depth of about 1500 Angstroms from surface of the substrate 100 and to a width less than about 900 Angstroms across an opening of the trench 140. As shown in FIG. 7, side walls of the trench 140 are sloped inward towards the center of the trench, so that the width of the trench 140 decreases towards a bottom of the trench 140. For example, the width of the trench 140 at the bottom may be in a range between about 700 Angstroms and about 750 Angstroms, where the opening of the trench 140 is about 900 Angstroms wide.

In some embodiments according to the invention, an oxide layer or a nitride layer may be formed on the bottom and on the sidewall of the trench 140 to reduce degradation of an insulation layer in the trench 140 caused by stress owing to expansion of the isolation region and/or by migration of some materials.

Referring to FIG. 8, a first insulation layer 150 is formed with sufficient thickness to fill the trench 140 and extend onto the substrate 100 outside the trench 140. In some embodiments according to the invention, the sufficient thickness is equal to the thickness of the insulation layer in a lowest density region (i.e., lowest population density offeatures or devices) on the substrate 100. In some embodiments according to the invention, the first insulation layer 150 is formed to a thickness of about 5500 Angstroms. Otherwise, if the first insulation layer 150 is formed to an insufficient thickness, the lowest density region on the substrate 100 may be damaged during CMP.

The thicknesses of the pad oxide layer 110, the pad nitride layer 120 and the anti-reflection layer 130, may combine with the depth of the trench 140 so that the thickness of the first insulation layer 150 may need to be about 3500 Angstroms to fill the trench 140 to the level of the antireflection layer 130. Further, even if a recess in the anti-reflection layer is considered, the total thickness needed for the first insulation layer 150 to bury the trench 140 may be in a range between about 3000 Angstroms and about 3200 Angstroms. Accordingly, in some embodiments according to the invention, the first insulation layer 150 is formed by depositing a high-density plasma (HDP) oxide layer via a chemical vapor deposition (CVD) process. The HDP oxide layer can have adequate “gap filling” properties in comparison with the other oxide materials.

A void 160 may occur despite filling the trench 140 with the HDP oxide layer using CVD. Specifically, the void 160 may be formed at a position within the HDP oxide layer (the first insulation layer 150) so that a subsequent planarization process thereon may expose the void 160. If the void 160 were left exposed, a conductive material (such as poly-silicon) may be deposited therein during a subsequent process, which may cause a short or bridge effect, thereby causing the device to possibly fail.

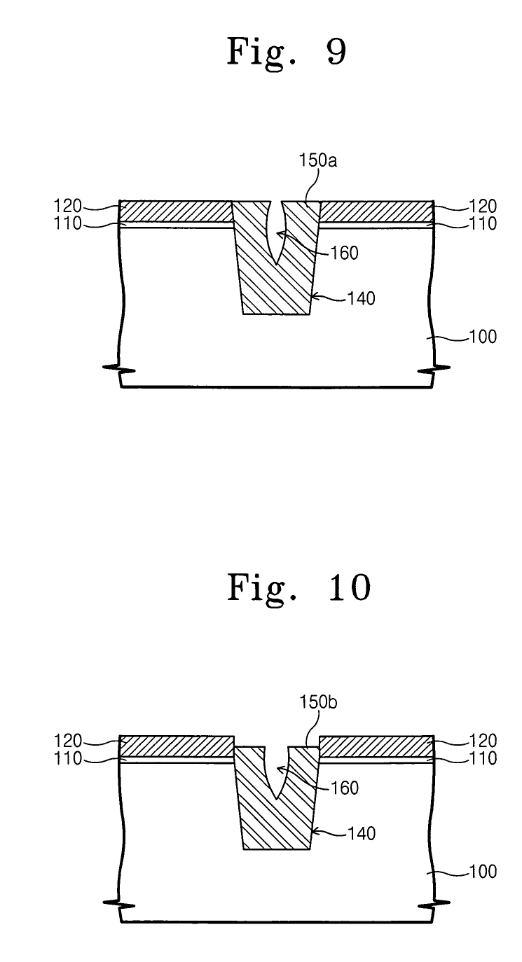

Referring to FIG. 9, the anti-reflection layer 130 and the first insulation layer 150, which are formed on a surface of the pad nitride layer 120 outside the trench 140, are removed and planarized by a CMP process using the pad nitride layer 120 as the polishing stop layer to provide the first insulation layer 150a. As shown in FIG. 9, the void 160, which can be formed in the first insulation layer 150, can be exposed by the CMP process. If, on the other hand, the planarization process of the first insulation layer 150 is performed using a wet etching or a plasma dry etching, the substrate 100 may be damaged if the wet etchant or plasma penetrates the exposed void 160.

It is possible to determine whether the void 160 is exposed on the planarized surface of the first insulation layer 150a by, for example, examining the surface of the substrate using an electron microscope. In some embodiments, a scanning electron microscope (SEM) is used to examine the surface of the substrate. Other devices may be used as well.

It will be understood that the profile of the void 160 in the first insulation layer 150a may be such that the ends of the void 160 may be narrow compared to a central portion of the void 160 when, for example, the width of the opening of the trench 140 is less than about 900 Angstroms. Accordingly, the cross-section of the void 160 (as shown) in the depth direction may be large compared to the cross-section in the width direction. As a result, the cross-sectional profile of the void 160 may appear to be oval. Therefore, if the void 160 is exposed by the CMP process, an opening of the void 160 in the surface of the first insulation layer 150 may be narrow in comparison to other cross-sections of the void 160.

Referring to FIG. 10, an upper portion of the first insulation layer 150a is removed, using wet etching, to provide the recessed insulation layer 150b having an increased opening of the void 160 at the surface of the recessed insulation layer 150b. Increasing the size of the opening may allow a second insulation layer to penetrate into the void 160 when formed on the first insulation layer 150a to be formed. Otherwise, it may be difficult to deposit the second insulation layer into the void through the relatively narrow opening shown in FIG. 9, which may result in the void being left unfilled by the second insulation layer. If the void were left unfilled by the second insulation layer, the void may be exposed again during a subsequent planarization process, which may cause problems similar to those discussed above.

It will be understood that the pad oxide layer 110 should not be subject to etching when forming the recessed insulation layer 150b. For example, if the first insulation layer 150a is etched excessively by the wet etch disclosed above, the pad oxide layer 110 may be exposed and, thereby, possibly damaged. Accordingly, it is preferable that the wet etching be performed without damaging the pad oxide layer 110. For example, the planarized first insulation layer 150a can be etched to remove about 100 Angstroms from the thickness of the first insulation layer 150a using HF etchant diluted in the ratio of 200:1 by mixing with deionized water to form the recessed insulation layer 150b. That is, the pad oxide layer 110 may be left covered by removing only a portion of the first insulation layer 150a that is above the pad oxide layer 110. In some embodiments according to the invention, less than 100 Angstroms may be removed from the thickness of the first insulation layer 150a. Other materials may be used to etch the first insulation layer 150a. Accordingly, the pad oxide layer 110 may be protected from etching damage. Further, in some embodiments according to the invention, the pad oxide layer 110 may be used as a gate oxide layer in a subsequently formed transistor device.

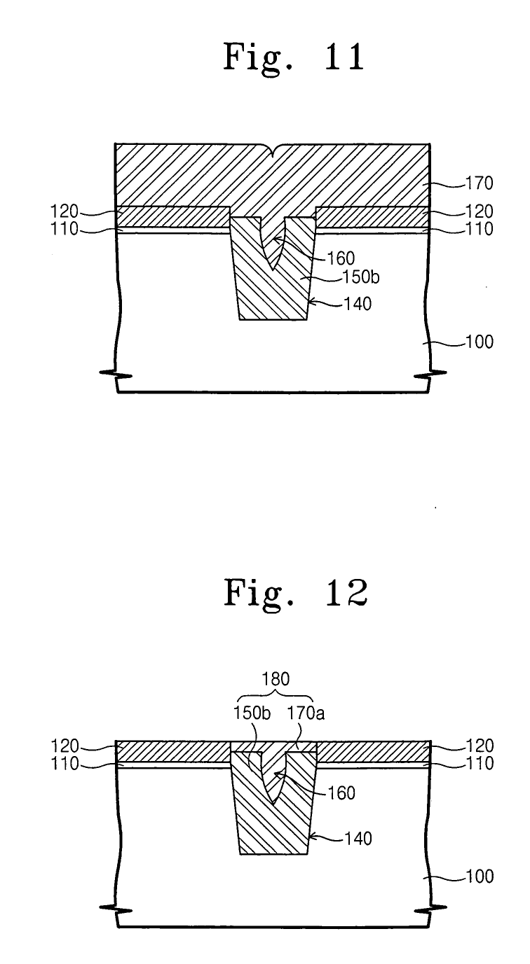

Referring to FIG. 11, a second insulation layer 170 is deposited in the void 160 through the increased opening in the recessed insulation layer 150b. The second insulation layer 170 is also deposited on the pad oxide layer 120 and on the substrate to a sufficient thickness to fill the void 160. In some embodiments according to the invention, the second insulation layer 170 is formed to a thickness of about 1000 Angstroms. The second insulation layer 170 may be formed by depositing a high-density plasma (HDP) oxide layer using CVD.

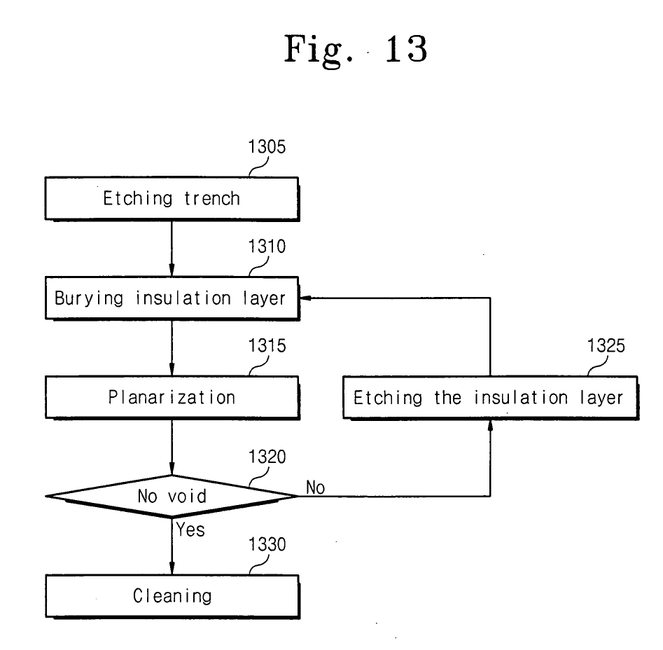

Referring to FIG. 12, the second insulation layer 170 is planarized by a CMP process using the pad nitride layer 120 as a polishing stop layer to form the second insulation layer 170a shown. As shown in FIG. 12, the void 160 remains covered beneath the surface of the second insulation layer 170a after the CMP process is performed to form the trench isolation region 180 including the first and second insulation layers 150b and 170a respectively, wherein the void 160 has been filled by the second insulation layer 170a.

In some embodiments according to the invention, as shown in FIG. 13, a trench is formed in the substrate (block 1305) and the (first) insulation layer is formed therein (block 1310) and is planarized (block 1315). The planarized surface of the (first) insulation layer is examined to determine whether a void is present at the planarized surface (block 1320). In some embodiments according to the invention, an electron microscope is used to examine the surface of the insulation layer. In some embodiments according to the invention, a scan electron microscope (SEM) is used. It will be understood that other techniques and/or devices (such as a scanning tunneling electron microscope (STEM) may be used. If a void is not present at the surface of the (first) insulation layer (block 1320), the surface is cleaned (block 1330) and processing may end.

However, if a void is present at the planarized surface of the (first) insulation layer(block 1320), the (first) insulation layer is etched to inside the trench (block 1325), which may increase the size of the opening of the void, and a (second) insulation layer is formed on the (first) insulation layer including in the void through the increased opening (block 1320). The second insulation layer is planarized (block 1315) and the planarized surface of the (second) insulation layer is examined to determine whether the void is present at the planarized surface of the second insulation layer (block 1320). If the void is not present at the surface of the second insulation layer (block 1320), the surface is cleaned (block 1330). The operations described above can be repeated until the void is filled.

It will be understood that when wet etching to partially remove the second insulation layer, it may be advantageous to avoid removing so much of the second insulation layer that the oxide layer 120 is exposed to the wet etch.

Many alterations and modifications may be made by those having ordinary skill in the art, given the benefit of present disclosure, without departing from the spirit and scope of the invention. Therefore, it must be understood that the illustrated embodiments have been set forth only for the purposes of example, and that it should not be taken as limiting the invention as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the invention.

What is claimed:

1. A method of forming a trench isolation region in a device substrate comprising:
planarizing a first insulation layer in a trench of a substrate so that the first insulation layer is removed from a surface of the substrate outside the trench and remains inside the trench, to form an opening to a void beneath a surface of the first insulation layer;
removing a further portion of the first insulation layer from inside the trench to increase the opening to the void; and
depositing a second insulation layer in the void in the first insulation layer through the increased opening.

2. The method according to claim 1 wherein removing a further portion of the first insulation layer from inside the trench further comprises:
removing the further portion of the first insulation layer; and then
ceasing removing the first insulation layer from inside the trench to avoid exposing an oxide pad layer located beneath the surface of the substrate.

3. The method according to claim 1 wherein removing a further portion of the first insulation layer comprises wet-etching the first insulation layer in the trench using an HF etchant diluted in a ratio of about 200:1 mixed with deionized water.

4. The method according to claim 1, wherein planarizing the first insulation layer is carried out by using chemical mechanical polishing.

5. The method according to claim 1 wherein the second insulation layer is deposited on the surface of the substrate outside the trench, the method further comprising:
planarizing the second insulation layer to remove the second insulation layer from the surface outside the trench and to avoid removing the second insulation layer from inside the trench.

6. The method according to claim 1 wherein planarizing a first insulation layer in a trench comprises:
planarizing the first insulation layer in a trench using chemical mechanical polishing; and then
examining the surface of the first insulation layer to determine if the opening of the void is present; and
cleaning the surface of the first insulation layer responsive to determining that the opening of the void is not present.

7. The method according to claim 6, wherein examining a surface of the first insulation layer comprises visually examining the surface using an electron microscope, a scanning electron microscope, or a scanning-tunneling electron microscope.

8. A method of forming a trench isolation region in a device substrate comprising:
polishing a first insulation layer in a trench of a substrate so that the first insulation layer is removed from a surface of the substrate outside the trench and remains inside the trench;
examining a surface of the first insulation layer in the trench to determine if an opening of a void in the first insulation layer is present;
cleaning the surface of the first insulation layer responsive to determining that the opening of the void is not present; and
etching a further portion of the first insulation layer from inside the trench to increase the opening to the void and depositing a second insulation layer in the void in the first insulation layer through the increased opening responsive to determining that the opening of the void is present on the surface of the first insulation layer in the trench.

9. The method according to claim 8 wherein etching a further portion of the first insulation layer is followed by:
planarizing the second insulation layer in the trench;
examining a surface of the second insulation layer in the trench to determine if an opening of a void in the second insulation layer is present;
cleaning the surface of the second insulation layer responsive to determining that the opening of the void is not present in the surface of the second insulation layer; and
etching a further portion of the second insulation layer from inside the trench to increase the opening to the void in the second insulation layer and depositing a third insulation layer in the void in the second insulation layer through the increased opening responsive to determining that the opening of the void is present on the surface of the second insulation layer in the trench.

10. The method according to claim 8 wherein wet or dry etching a further portion of the first insulation layer from inside the trench further comprises:
removing the further portion of the first insulation layer; and then
ceasing removing the first insulation layer from inside the trench to avoid exposing an oxide pad layer located beneath the surface of the substrate.

11. The method according to claim 8 wherein etching a further portion of the first insulation layer comprises wet-etching the first insulation layer in the trench using an HF etchant diluted in a ratio of about 200:1 mixed with deionized water.

12. The method according to claim 11 wherein wet-etching the first insulation layer comprises wet-etching the first insulation layer to remove about 100 Angstroms from the surface of the first insulation layer.

13. The method according to claim 8 wherein examining a surface of the first insulation layer comprises visually examining the surface using an electron microscope, a scanning electron microscope, or a scanning-tunneling electron microscope.

14. A method of forming a trench isolation region in a device substrate comprising:
forming a pad oxide layer and a pad nitride layer on a substrate;
patterning the pad nitride layer to provide a pattern thereon;
forming a trench through the pad oxide layer and the pad nitride layer into the substrate via the pattern;
forming a first insulation layer in the trench extending onto a surface of the pad nitride layer outside the trench, the first insulation layer having a void therein beneath the surface of the first insulation layer;
planarizing the first insulation layer using chemical mechanical polishing so that the first insulation layer is removed from the surface of the pad nitride layer outside the trench and remains inside the trench, to form an opening to the void beneath the surface of the first insulation layer;
removing a further portion of the first insulation layer from inside the trench using a etching etch process to increase the opening to the void;
depositing a second insulation layer in the void in the first insulation layer through the increased opening and extending onto the surface of the pad nitride layer outside the trench; and
planarizing the second insulation layer using chemical mechanical polishing so that the second insulation layer is removed from the surface of the pad nitride layer outside the trench and remains inside the trench.

15. The method according to claim 14 wherein removing a further portion of the first insulation layer from inside the trench further comprises:
removing the further portion of the first insulation layer; and then
ceasing removing the first insulation layer from inside the trench to avoid exposing the oxide pad layer inside the trench along a side wall thereof.

16. The method according to claim 14 wherein removing a further portion of the first insulation layer comprises wet-etching the first insulation layer in the trench using an HF etchant diluted in a ratio of about 200:1 mixed with deionized water.

17. The method according to claim 16 wherein wet-etching the first insulation layer comprises wet-etching the first insulation layer to remove about 100 Angstroms from the surface of the first insulation layer.

18. The method according to claim 14 wherein forming a trench comprises forming the trench to a depth of about 1500 Angstroms into the substrate;

19. The method according to claim 14 wherein forming a pad oxide layer and a pad nitride layer comprises:
forming the pad oxide layer to a thickness of about 100 Angstroms; and
forming the pad nitride layer to a thickness of about 400 Angstroms.

20. The method according to claim 14 wherein forming a pad oxide layer and a pad nitride layer further comprises:
forming an anti-reflection layer to a thickness of about 1500 Angstroms on the pad nitride layer.
